(19) United States
(12) Patent Application Publication
(10) Pub. No.: US 2013/0000552 A1
(43) Pub. Date: Jan. 3, 2013

(54) DEVICE AND METHOD FOR PRODUCING BULK SINGLE CRYSTALS

(75) Inventor: Jason Schmitt, Wichita, KS (US)

(73) Assignee: NITRIDE SOLUTIONS INC., Wichita, KS (US)

(21) Appl. No.: 13/171,028

(22) Filed: Jun. 28, 2011

(51) Int. Cl. C30B 25/16; C30B 25/10

(52) U.S. Cl. 118/696; 118/708; 118/712

(57) ABSTRACT

The disclosure provides a device and method used to produce bulk single crystals. In particular, the disclosure provides a device and method used to produce bulk single crystals of a metal compound by an elemental reaction of a metal vapor and a reactant gas by an elemental reaction of a metal vapor and a reactant gas.

### FIELD OF INVENTION

The present disclosure relates to a device and method used to produce bulk single crystals. In particular, the present disclosure relates to a device and method used to produce bulk single crystals of a metal compound by an elemental reaction of a metal vapor and a reactant gas.

### BACKGROUND

Crystalline metal compounds such as aluminum nitride and zinc oxide possess desirable properties for semiconductor applications including wide energy bandgaps, high-breakdown electrical fields, and high thermal conductivity. These properties are prominent in crystalline series III-V metal compounds having few defects. As such, it is desirable to produce large crystals for use in semiconductors; however, it may be difficult to produce large crystals having few defects.

Currently, a number of different methods are used, to produce large, low-defect crystalline metal compounds; however, each method has inherent limitations. A conventional sublimation method, shown in FIG. 1, melts a polycrystalline form of the desired crystal compound in a closed crucible, causing the crystal compound to sublimate slowly to the top of the crucible where it condenses. The top of the crucible is held at a lower temperature than the bottom of the crucible. The problem with this method is that single crystal production inherently limits the amount or quality of the crystals produced. The slow rate of evaporation of the polycrystalline compound used in the sublimation process relative to the evaporation rate of a pure metal, as shown in FIG. 2, limits the crystal growth rate in the sublimation process to relatively low rates.

Another method is the hydride vapor phase epitaxy (HVPE) method, shown in FIG. 3, for the production of aluminum nitride. In this method, pure aluminum vapor is combined with a halide gas such as HCl to form AlCl₃. The AlCl₃ is then combined with ammonia gas in a growth zone. At this growth zone, aluminum nitride is formed, and the HCl byproduct of the reaction is exhausted away.

Furthermore, other methods may facilitate other unwanted chemical reactions. For example, nitrozation at the surface of a melted metal feedstock, such as aluminum, in contact with a reactive gas, such as nitrogen or ammonia, may form more stable compounds at the exposed surface of the metal feedstock. These stable compounds greatly reduce the amount of vaporized feedstock produced relative to an initial rate of vaporization. In addition, as existing methods typically make use of a closed reactor, the crystals are formed using a batch process limited by the holding capacity of the crucibles used to vaporize the crystal compound or metal.

There exists a need for devices and methods of growing single low-defect crystals of metal compounds at a high growth rate. Further, a need exists for an efficient reactor to produce crystals that are not limited in size by the batch processing of a limited amount of feedstock.

### SUMMARY

An open-flow reactor for producing single crystals of a metal compound that overcome the limitations described above has been developed. The open-flow reactor incorporates a continuous addition of replenishable feedstock, making possible the continuous production of the single crystals to any desired size, unlimited by the availability of feedstock. Furthermore, the design of the open-flow reactor incorporates repositioning the growing crystal within the reactor to maintain the exposed surface of the crystal at a temperature conducive to rapid crystal growth. The exposed surface of the crystal is positioned to avoid exposing the already formed portion of the crystal to unnecessary mechanical or thermal stresses that may induce undesired voids within the crystal. Using the open-flow reactor, high-purity single crystals having a diameter of up to about six inches may be grown. The maximum crystal diameter may be limited only by the center-to-edge temperature uniformity within the crystal.

The open-flow reactor provides for the growth of a single crystal of a metal compound by an elemental reaction of a metal vapor and a reactant gas. The reactor includes a metal vapor system to continuously provide the metal vapor to the reactor. For example, the metal vapor system may include an electrical arc which vaporizes a metal wire as the wire is inserted into the reactor. In addition, the metal wire may be provided from a spool, providing essentially unlimited metal vapor to the reactor.

The reactor further provides a rotation-translation-weighing system to monitor the weight of the single crystal as it grows and to reposition the crystal to a position suitable for continued growth within the reactor, as the crystal increases in size. The rotation of the single crystal may reduce variations in the thickness of the crystal as it condenses from the metal compound vapor within the reactor. The movement of the rotation-translation-weighing system allows the crystal to be repositioned within the reactor to a location having reaction conditions at which rapid growth may be achieved. The weight of the growing crystal obtained by the rotation-translation-weighing system may be used to monitor various process parameters, such as overall crystal size or crystal growth rate.

The reactor is an open-flow reactor that includes a metal feedstock and a metal heating source for vaporizing the metal feedstock. The metal vapor reacts with a reactive gas to grow the crystals. The metal feedstock may include one or more pure metals, metal nitrides, and/or a doping metal. A doping metal may be used to intentionally dope the crystal during growth. The reactor includes a crystal growth substrate that is mechanically connected to an actuator for positioning the crystal growth substrate within the open-flow reactor. A force transducer is mechanically connected to the crystal growth substrate to monitor the weight of the single crystal as it grows.

The reactor further includes a metal heating source that includes a vaporization region situated between a vaporization inlet and a vaporization outlet. A metal feedstock that includes a metal storage container and a protruding free end is also included in the reactor, and the protruding free end is inserted through the vaporization inlet into the vaporization region.

One embodiment of the reactor also includes a gas supply tube that incorporates an exit port at one end and a gas supply connection at an opposite end of the gas supply tube. The exit port is situated near the vaporization inlet and is aimed at the vaporization region. A connection fitting of a gas source, which also includes a pressurized gas container, is hydraulically connected to the gas supply connection of the gas supply tube.

A hollow thin-walled heater can be included in the reactor. The heater defines a continuous internal volume that opens to a heater inlet formed at one end of the heater and to a heater exit formed at an opposite end of the heater. The heater inlet is hydraulically sealed to the vaporization outlet of the metal heating source. The continuous internal volume defined within the heater includes a mixing chamber, a crystal growth chamber that includes a growth inlet and a growth outlet, and a post-reaction chamber. The mixing chamber opens to the heater inlet at one end and to the growth inlet at its opposite end. The crystal growth chamber opens to the growth inlet at one end and the growth exit at its opposite end. The post-reaction chamber opens to the growth exit at one end and to the heater exit at its opposite end.

A thin sheet recrystallization substrate is situated within the crystal growth chamber. The substrate has a recrystallization face and an opposing mounting face. The recrystallization face is exposed to the growth inlet of the crystal growth chamber. The mounting face of the recrystallization substrate is attached to the attachment face of a substrate chuck. The substrate chuck has a rod attachment face opposite to its attachment face. The rod attachment face of the substrate chuck is attached to an attachment fitting at one end of an elongate support rod. The opposite end of the support rod has an actuator fitting that is attached to a weight sensor and at least one actuator.

The reactor of this embodiment also includes a reactor housing that includes a thin-walled hollow reactor body, an inlet end cap, and an outlet end cap. The reactor body defines a reactor volume sealed at one end by an interior surface of the inlet end cap and by an interior surface of the outlet end cap at an opposite end of the reactor body. The vaporization inlet of the metal heating source is sealed to the interior surface of the inlet end cap and opens to the exterior of the reactor housing through a reactor inlet channel running through the inlet end cap. The heater exit is sealed to the interior surface of the outlet end cap and opens to the exterior of the reactor housing through a reactor outlet channel running through the outlet end cap. At least one purge tube runs through the outlet end cap from the exterior of the reactor housing to the reactor volume external to the continuous internal volume of the heater.

Each purge tube includes a purge tube inlet at the end of the purge tube in contact with the reactor volume, and a vacuum attachment fitting at an end of the purge tube external to the reaction housing. At least one vacuum tube of a vacuum source is hydraulically connected to the vacuum attachment fitting of the one or more of the one or more purge tubes. Another of the at least one vacuum tubes may be connected to the heater exit. The opposite ends of the at least one vacuum tubes are hydraulically connected to a vacuum pump.

Embodiments of the disclosure may further provide a method of producing a single crystal of a metal compound by an elemental reaction of a metal vapor and a reactant gas that includes vaporizing a metal to produce the metal vapor. A reactant gas is contacted with the metal vapor, and the resulting mixture is heated to produce the metal compound. The metal compound is contacted with a crystallization substrate to precipitate a single crystal.

### BRIEF DESCRIPTION OF DRAWINGS

FIG. 1 is a drawing illustrating a prior art sublimation crystal production method.

FIG. 2 is a graph summarizing the evaporation rate of various feedstocks used in crystal production methods.

FIG. 3 is a drawing illustrating a prior art HVPE crystal production method.

FIG. 4 is a block diagram of an exemplary open flow reactor system.

FIG. 5 is a drawing of an exemplary upflow reactor system 400.

FIG. 6 is a drawing of an exemplary two-wire metal vapor system.

FIG. 7 is a drawing of another exemplary two-wire metal vapor system.

FIGS. 8A-8F are drawings of exemplary two-electrode metal vaporization arc arrangements.

FIGS. 9A-9E are drawings of exemplary single-electrode metal vaporization arc arrangements.

FIG. 10 is a drawing of an exemplary inductive plasma metal vaporization device.

FIG. 11 is a drawing of an exemplary heater.

FIG. 12 is a drawing of an embodiment of an upflow reactor system 400.

FIG. 13 is a drawing of an exemplary substrate chuck and housing.

FIGS. 14A-14E are drawings showing the repositioning if a growing crystal within the growth chamber by an exemplary RTW system.

FIG. 15 is a drawing of an exemplary downflow reactor system 400.

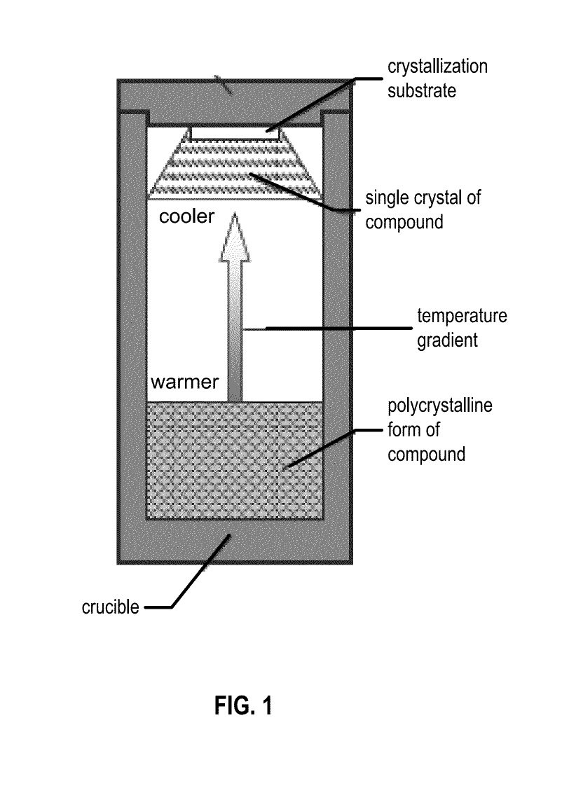

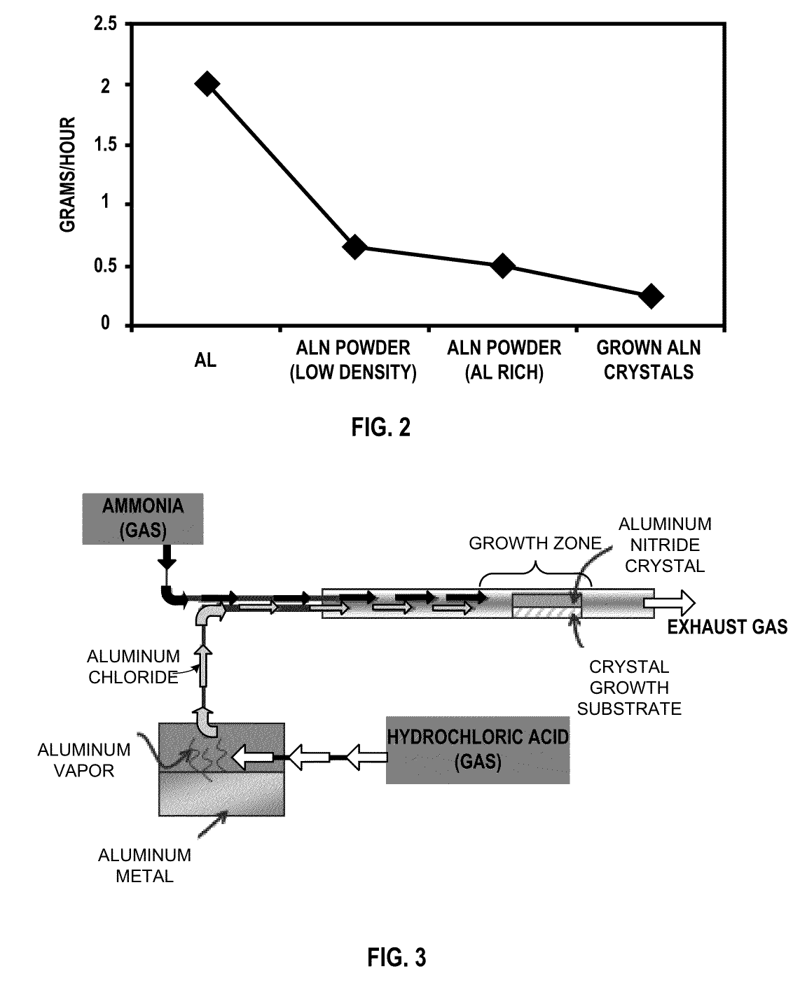

### DETAILED DESCRIPTION

Unless otherwise defined, all technical and scientific terms used herein have the same meaning as commonly understood by one of ordinary skill in the art to which this disclosure belongs. All publications, patent applications, patents, and other references mentioned herein are incorporated by reference in their entirety.

### 1. Open Flow Reactor System

In various embodiments, the present disclosure provides an open flow reactor system 400 for the growth of a single crystal of a metal compound by an elemental reaction of a metal vapor and a reactant gas. The disclosure includes an open flow reactor designed and dimensioned to provide for continuous growth of bulk crystals. The disclosure further relates to a method of producing bulk crystals.

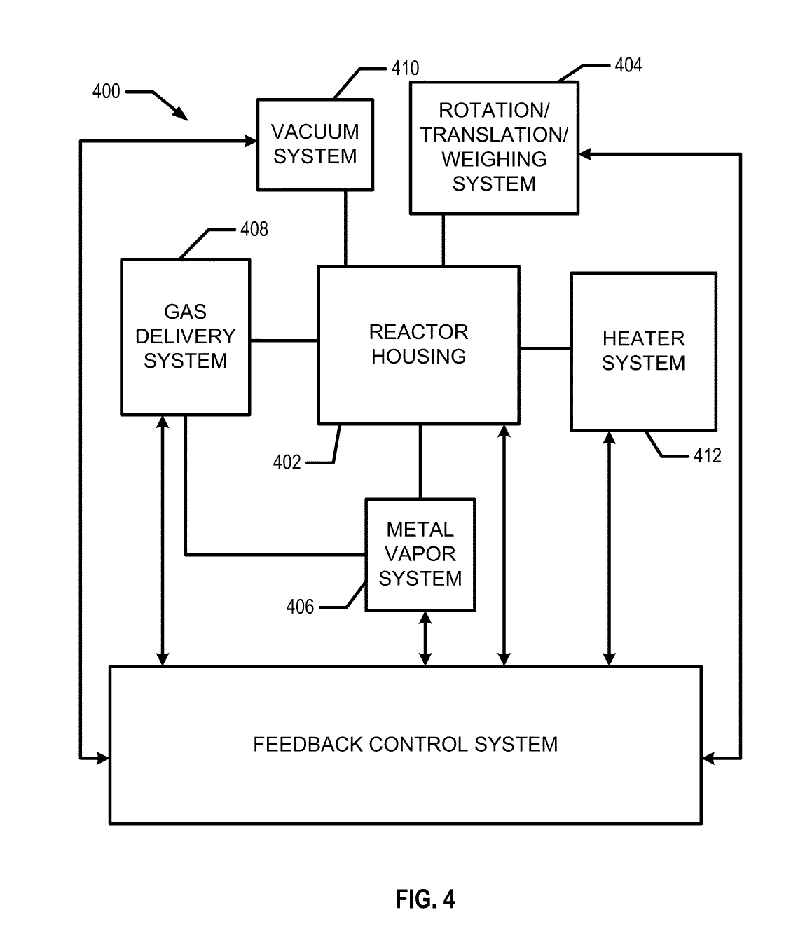

FIG. 4 is a block diagram illustrating exemplary elements of the open flow reactor system 400. The open flow reactor system 400 grows large bulk crystals by continuously reacting a metal vapor and a reactive gas, under controlled conditions. The open flow reactor system 400 features a number of components and elements, including a reactor housing 402, a rotation/translation/weighing system 404, a metal vapor production component 406, a gas delivery system 408, a heating system 412, a vacuum system 410, and a real-time feedback control system 414 to facilitate the continuous growth of bulk crystals.

The reactor housing 402 is the encasement where the reaction between the metal vapor and reactant gas occurs to produce the resulting crystal product. A rotation/translation/weighing system 404, connected to the reactor housing 402, obtains real-time feedback about the production quality and amount of production of the single crystal. A metal vapor system 406 includes a metal heating source to vaporize the metal feedstock. The resulting metal vapor flows to the reactor housing 402 where it is mixed with the reactant gas supplied by a gas delivery system 408.

The gas delivery system 408 provides one or more reactant gases, such as nitrogen, to both the reactor housing and the metal vapor system. The reactant gases may be used to cool the one or more seals of the reactor housing 402. The reactant gases may also be used to purge the interior volume of the reactor housing 402 by removing any reactive oxygen present in the reactor housing 402. The gas delivery system 408 also connects to the metal heating source of the metal vapor system 406 to provide one or more reactant gases, such as nitrogen and/or a doping gas, before and/or after providing the metal vapor and reactant gas to the reactor housing 402.

Connected to the reactor housing 402 is a vacuum system 410 used to remove the one or more reactant gases provided by the gas delivery system 408 to purge the reactor housing 402. The amount of vacuum pressure applied to the reactor housing 402 may be modified to control the rate at which gases flow through the reactor housing. The heater system 412 heats the interior of the reactor housing 402 using for example, a radio frequency induction heater.

In various embodiments, the reactor system 400 may be configured as an upflow reactor in which the metal is vaporized and injected into the bottom of the reactor housing 402, in which the gas flow direction is toward the top of the reactor housing. In other embodiments, the reactor system 400 may be configured as a downflow reactor system 400 in which the metal is vaporized at the top of the reactor housing 402 and the gas flow direction is in the downward direction. In other embodiments, any other angular orientation of the reactor system 400 may be used ranging between 0° (upflow design) and 180° (downflow design). In yet other embodiments, the angular orientation may vary during the operation of the reactor system 400. In the various embodiments, the metal vapor, reactive gases, and other components used in the crystal growth are introduced to the reactor housing 402 through an inlet end and removed via an exit end.

Alternatively, the reactor system 400 may configured in any suitable orientation including a horizontal orientation, a vertical orientation, a 45° orientation relative to a vertical reference, and any intermediate orientation depending on the desired use of the reactor system 400.

In addition to the specific systems described above, the processes performed by the systems of the open flow reactor system 400 may be controlled by a control system (not shown). The control system may include manual inputs to the various devices included in the systems of the open flow reactor system 400, or the control system may be an automated control system that autonomously controls the processes of the open flow reactor system. The control system may be an open-loop system, in which predetermined commands to modify the processes of the reactor system 400 are issued sequentially to perform the functions of the reactor system. Alternatively, the control system may process feedback information measured from one or more sensors including a weight sensor, a temperature sensor, a pressure sensor, or a flow velocity sensor, to develop commands used to perform the functions of the reactor system 400.

The systems and components of the reactor system 400 described above, as well as exemplary embodiments of the reactor system are described in detail below.

### 2. Reactor Housing

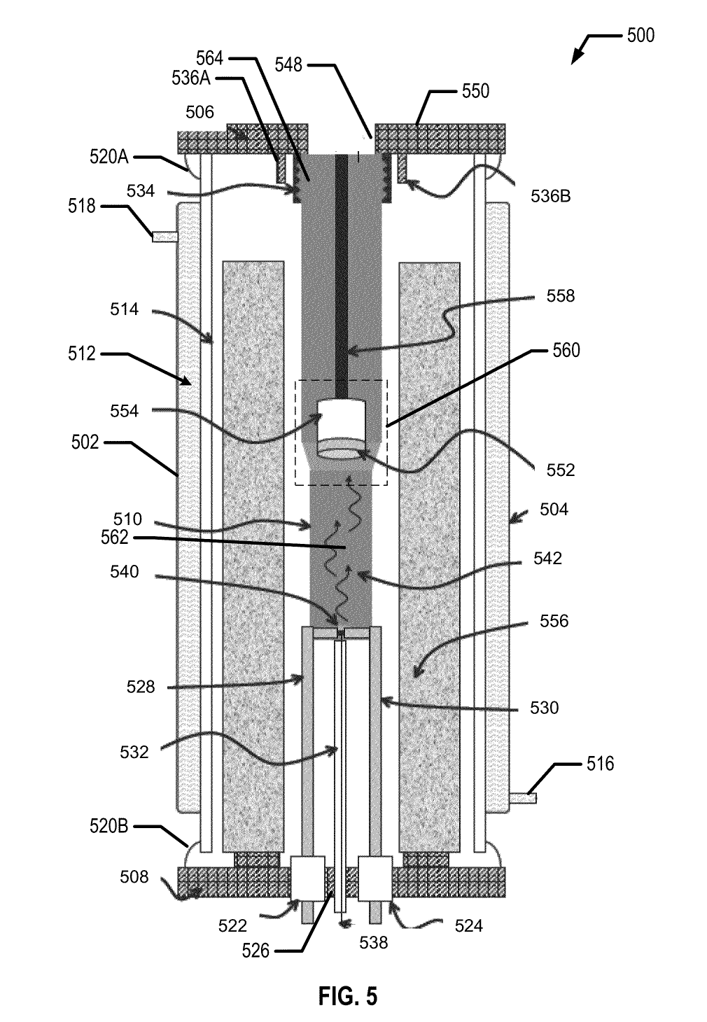

An internal view of an embodiment of the reactor system is generally indicated as 500 and shown in FIG. 5. The reactor housing 502 is where the reaction between the type III-V metal and at least one reactant gas occurs to form the single crystal of the metal compound. The reactor housing 502 includes three major parts: a sidewall 504 and a pair of end caps 506 and 508.

a. Reactor Sidewall

The sidewall 504 provides mechanical support for the related components of the reactor housing 502. The sidewall 504 also forms a hydraulically sealed container within which the crystal formation takes place. In addition, the sidewall 504 insulates the heating components located inside the reactor housing 502 and protects the environment outside of the reactor housing 500 from the high temperatures present inside the reactor housing 502. The sidewall 504 is constructed of at least a single layer of material, but can be constructed of two or more layers of material. The material of the sidewall 504 can be a single uniform material or a combination of a number of materials.

Materials suitable for use in the construction of the sidewall 504 are selected to maintain structural integrity at pressures within the reactor housing 502 ranging from about 0.01 ATM to about 20 ATM and temperatures up to about 2500° C. that may occur during the crystal production process. In addition, suitable materials are selected to resist thermal fatigue induced by the thermal cycles between room temperature and the operating temperatures of the reactor housing 502. Materials suitable for use in the construction of the side wall include stainless steel, quartz, aluminum borate and similar glasses, Ni, Ti, and ceramic materials such as alumina, zirconia, and magnesia that are capable of tolerating the high temperature conditions of the reactor housing 502. Combinations of these materials may also be used.

The sidewall 504 may also include active cooling elements to cool the reactor housing 502 and/or provided greater protection to the environment surrounding the reactor housing 502. Non-limiting examples of active cooling elements include radiative cooling elements, such as heat vanes attached to the outer layer of the sidewall 504, and conductive cooling elements, such as one or more heat sinks in contact with any one or more of the layers of the sidewall 504. Other examples are convective cooling elements, such as one or more fluid-cooled layers of the sidewall 504. An example of a fluid-cooled layer within the sidewall 504 is illustrated in FIG. 5.

The fluid-cooled sidewall 504, as illustrated in FIG. 5, may include a fluid-cooled outer sidewall 512 that encases an uncooled inner sidewall 514. In this embodiment, the outer sidewall 512 may form a hollow container through which the cooling fluid may circulate, causing convective cooling to the sidewall 504. For example, the cooling fluid may be pumped under pressure into a fluid inlet 516 and exit via a fluid outlet 518. In other embodiments, the fluid-cooled outer sidewall 512 may include capillary tubes, baffles, or other convective cooling elements known in the art.

The fluid used to provide convective cooling may be any cooling fluid known in the art. The cooling fluid may be a gas such as air, nitrogen, helium, carbon dioxide, or a combination of gases. Alternatively, the cooling fluid may be a liquid such as water, ethylene glycol, diethylene glycol, propylene glycol, betaine, polyalkylene glycols, mineral oils, castor oil, silicone oils, fluorocarbon oils, or a combination of liquids. In an exemplary embodiment, water is used as the cooling fluid.

The sidewall 504 may also include seals 520A and 520B to hydraulicly seal of the interior of the reactor housing 502. The material used in the construction of the seals is selected to maintain function under the pressure and temperature ranges described above. The material of the seals 520A and 520B is also selected to maintain some degree of flexibility and maintain a seal in the presence of thermal expansion and contraction, vibrations, or other movements of components of the reactor housing 502. Any material known in the art for forming seals around devices having wide ranges of operating temperatures and pressures may be used. Non-limiting examples of materials suitable for use in the construction of the seals 520A and 520B include copper, rubber, and silicon.

b. End Caps

End caps 506 and 508 seal the respective ends of the reactor housing 502. The end caps 506 and 508 are attached to the opposed ends of the side wall 504 that enclose the interior space of the reactor housing 502 and provide sealed openings through which the metal vapor, one or more reactant gases, and unprecipitated crystalline metal compound may enter and exit the reactor housing 502. The end caps 506 and 508 also provide fittings to which other systems of the reactor housing 502, such as the metal vapor system 406 or heater system 412, may be attached.

The reactor housing 500 may include an inlet end cap 508 that includes openings 522 and 524 through which electrodes 528 and 530 may be inserted to connect the metal vapor system 406 to the reactor housing 402 (see FIG. 4). The inlet end cap 508 may further contain an opening 526 through which a gas pipe 532 may be inserted to connect the gas delivery system 408 to the reactor housing 402 and gas delivery system 408. The reactor housing 502 may further include an outlet end cap 506 that contains a heater connection fitting 534 to which the heater 510 may be attached. In addition, the outlet end cap 506 may include one or more purge tubes 536A and 536B to which the vacuum system 410.

Suitable materials for the construction of the end caps are selected to maintain function at temperatures of at least 300° C. and up to about 2500° C. and pressures ranging from about 0.01 ATM to about 20 ATM, and to possess material properties for mounting fittings such as threaded male or female fittings. Non-limiting examples of materials suitable for the construction of end caps 506 and 508 include stainless steel, Ni, Ti, Mo, and combinations thereof.

Any alternative device for sealing high-temperature pressurized or evacuated vessels known in the art may be used in various embodiments without departing from the spirit of this disclosure.

### 3. Metal Vapor System

The metal vapor system 406 supplies metal vapor used in producing the single crystal of the metal compound. In general, the metal vapor is produced by heating an amount of one or more metals to a temperature above the boiling point of the metal(s), causing the metal(s) to vaporize. Non-limiting examples of suitable metals include Mg, Al, Sc, Ti, V, Cr, Fe, Co, Ni, Cu, Zn, Zr, Nb, Mo, Cd, In, Sn, Ta, W, metal nitrides, and alloys thereof. Depending on the particular metal(s) to be vaporized, the temperature may range from about 750° C. to about 5600° C. The metal vapor system is designed to minimize undesired chemical reactions at the surface of the vaporizing metal, such as nitrozation, which may potentially limit the vaporization rate of the metal(s).

Various embodiments of the metal vapor system 406 may include a metal heating source including but not limited to an electrical arc, a DC plasma source, an induction coupled plasma source, a laser source, and a microwave source. The metal heating source may be any device that can heat metal to a boiling point. In some embodiments, one or more metal heating sources are used to vaporize the metal(s). In one example, an electrical arc and a DC plasma source may be used. In another example, a combination of multiple electrical arcs, DC plasma sources and an induction coupled plasma source may be used to vaporize the metal(s). In these embodiments, the metal heating sources may have varied and/or multiple spatial orientations within the reactor system 400 and remain within the scope of the disclosure.

The heating source(s) may be situated between a vaporization inlet and a vaporization exit. A metal feedstock is inserted into the metal heating source(s) through the vaporization inlet, and the vaporized metal exits the heat source(s) through the vaporization exit. In addition to the metal feedstock, at least one reactive gas may be introduced into the vaporization inlet and help remove the vaporized metal by convection.

The elements of an exemplary metal vapor system 406 are illustrated in FIG. 5. In this embodiment, a metal wire 538 is drawn up to an electrical arc 540 formed between electrodes 528 and 530. The metal wire 538 is fed through the electrical arc 540 that vaporizes a small length of the wire 538 into metal vapor 542. The metal vapor 542 is conveyed to the heater 510 by one or more reactant gases supplied by the gas pipe 532.

An external arc power supply (not shown) may generate the power for the electrical arc 540. The metal wire 538 may be drawn up to the electrical arc 540 area by an actuator such as a stepper motor (not shown). The electrical arc 540 and the feed of the metal wire 538 may be pulsed and timed together so that a new section of metal wire 538 is vaporized by each new pulse of the electrical arc 540. Alternatively, the electrical arc 540 may be constant and the metal wire 538 may be fed step-wise into the electrical arc 540.

Any suitable material may be used to construct the electrodes 538 and 540. Conductive materials with relatively high boiling points may be selected to avoid vaporization of the electrode material and inadvertent contamination of the single crystal produced by the reactor housing 502. Non-limiting examples of materials suitable for the construction of electrodes 538 and 540 include tungsten, copper, zirconium, carbon, and boron.

In other embodiments, one or both electrodes 538 and 540 may be replaced with one or more separate metal feedstocks. In these embodiments, the one or more metal feedstocks are connected to the electrical power source and act as consumable electrodes.

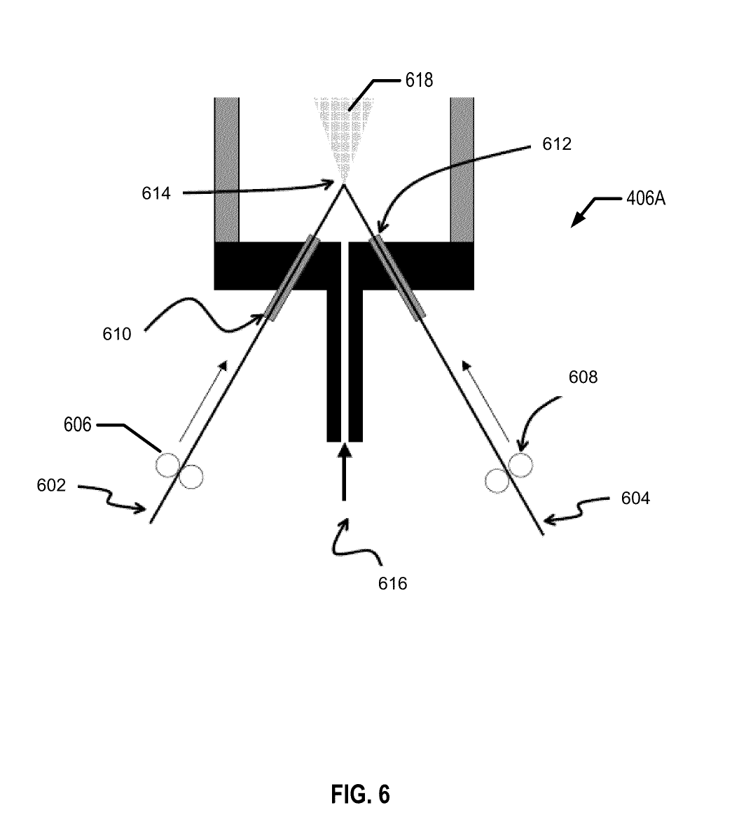

An exemplary embodiment of a metal vapor system 406A in which both electrodes 538 and 540 are replaced by metal feedstock is illustrated in FIG. 6. In this embodiment, the metal feedstock is provided as two metal wires 602 and 604 that are brought together by opposing stepper motors 606 and 608. The two metal wires 602 and 604 are fed through electrical contacts 610 and 612 respectively, where the metal wire 602 receives a positive charge and the other metal wire 604 receives a negative charge. As the charged wires 602 and 604 are brought closer together, an electrical arc 614 is produced between the wires 602 and 604. The heat of the electrical arc 614 vaporizes a small length of each of the wires 602 and 604. A reactive gas such as nitrogen is provided to the middle of the electrical arc 614 through a gas pipe 616. The result is a high temperature metal/gas mixture 618 which is transported to the heater system 412.

The material of the metal feedstock is selected based on the desired single crystal metal compound to be produced in the reactor housing 502. Non-limiting examples of suitable metals for the metal feedstock include Mg, Al, Sc, Ti, V, Cr, Fe, Co, Ni, Cu, Zn, Zr, Nb, Mo, Cd, In, Sn, Ta, W, and combinations thereof. In a preferred embodiment, the metal feedstock is aluminum or any alloy thereof.

The metal feedstock may consist of a single metal element. Alternatively, the metal feedstock may include a metal element and a second doping metal. The doping metal may be introduced into the reactor housing 502 by using a number metal feedstocks, where one metal feedstock is a pure metal and a second feedstock contains a selected doping metal. When vaporized, the pure metal and the doping metal form a metal vapor mixture which may condense into a single crystal of a doped metal compound. Alternatively, the metal and the doping metal may be combined within the same metal stock as an alloy. The metal feedstock may be introduced into the electrical arc 614 as a uniform composition to form a single crystal of a single homogeneous composition. Alternatively the composition of the metal feedstocks may be changed either abruptly or gradually to produce single metal compound crystals having discrete layers of changing composition or a gradually changing composition within the single crystal, respectively.

The metal feedstock may be supplied in any suitable form including but not limited to metal powder, a metal wire, a metal tube, a metal rod, and a metal bar. The metal feedstock may be supplied in the form of a container of metal powder, a spool of metal wire or metal tubing, or a sequence of metal rods or bars. If the metal feedstock is supplied in the form of a metal wire, the wire diameter may range from about 0.001 to about 1 cm. In a preferred embodiment, the metal feedstock is supplied as a spool of metal wire. In yet another embodiment, a liquid metal source, including but not limited to Al, Ga, and In, may be injected into the reactor without departing from the spirit of the disclosure.

In other embodiments, the metal vapor may be produced by vaporizing a metal nitride powder, or a mixture of metal(s) and metal nitride powder(s). By way of example and not limitation, the metal vapor may be produced by vaporizing a mixture that is 25% Al wire and 75% AlN powder. In this example, the Al wire and A1N powder may be introduced onto reactor through the same or different inlets. The metals may also be vaporized by the same or different metal heating sources.

In another example, a mixture that is 10% Al powder and 90% AlN powder may be vaporized. In this example, the powders may be mixed prior to being introduced into the reactor. In other examples, any number of metal powders and/or metal nitride powders may be mixed and vaporized. In a preferred embodiment, the powder particles range in diameter from 1 mm to 1 nm.

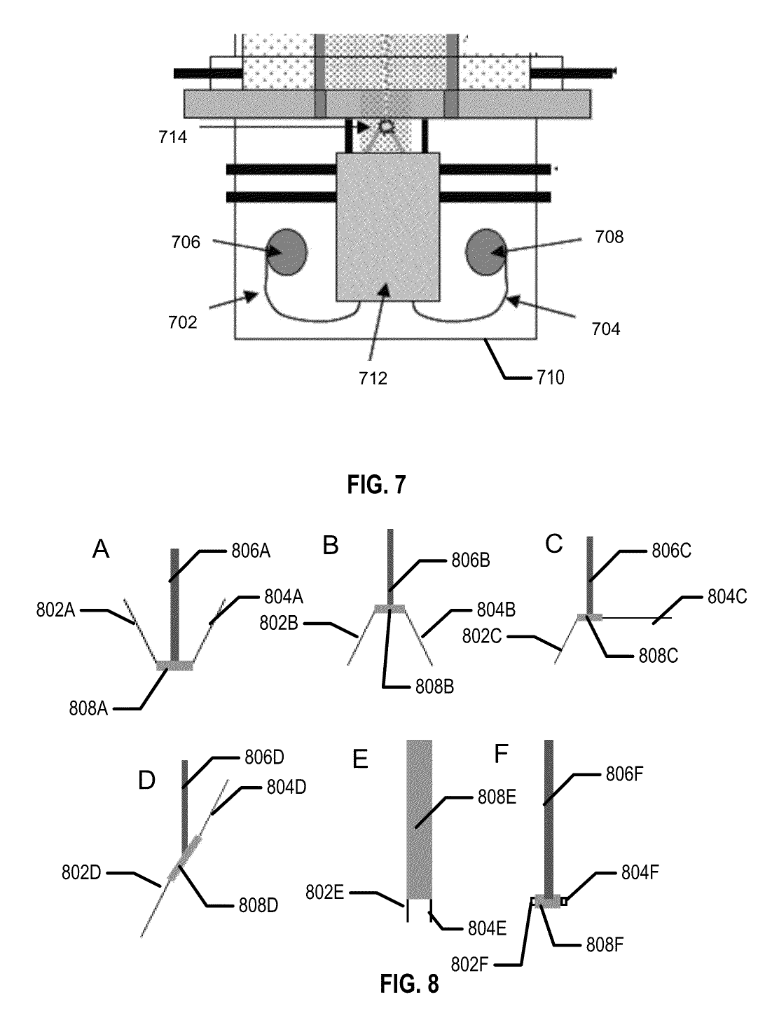

An exemplary embodiment of a spool-fed metal vapor system 406B is illustrated in FIG. 7. Two metal wire 702 and 704 are reeled off of wire spools 706 and 708 respectively stored inside the wire arc sub-system housing 710. The wires 702 and 704 are drawn together by stepper motors (not shown) within the wire arc head main unit 712. At the point the two wires 702 and 704, an electrical arc 714 is produced that vaporizes a small length of each of the wires 702 and 704.

Electrodes to generate the electric arc may be any orientation so long as a small gap remains between the electrodes to form an electrical arc. FIGS. 8A-8F illustrate various embodiments of the electrodes 802 A-F and 804 A-F used to vaporize metal wires 806 A-F with arc 808 A-F. FIG. 8A illustrates a “V” configuration having electrodes 802A and 804A producing an arc 808A which vaporizes the metal wire 806A as it is fed into the electrical arc 808A. FIGS. 8B-8D similarly illustrate an “inverted V” configuration (FIG. 8B), a single angled electrode configuration (FIG. 8C), and a “slash” configuration (FIG. 8D). FIG. 8E is a top view of a configuration in which the electrodes 802E and 804E are arranged in a parallel configuration, forming am electrical arc 808E. The side view of the parallel configuration is shown in FIG. 8F, in which the metal wire 806F is fed into the electrical arc 808F.

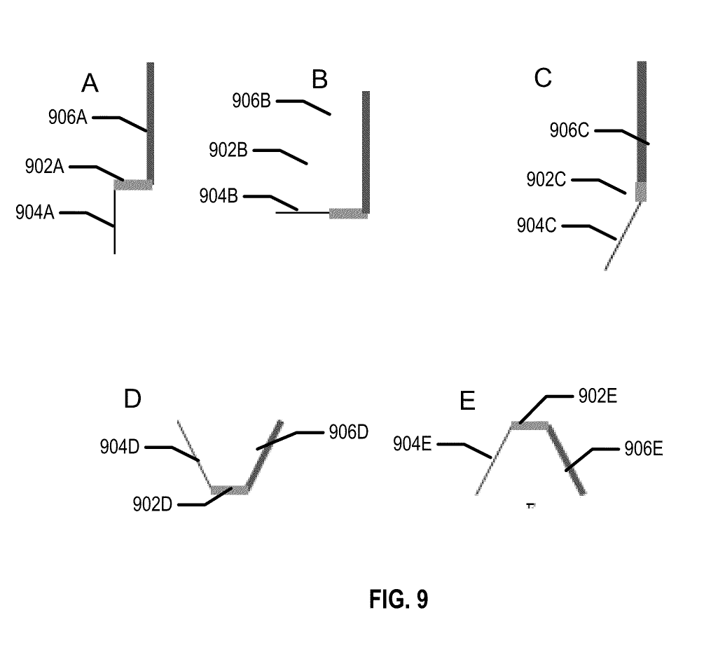

FIG. 9A through 9E illustrates a number of alternative arrangements of a single-electrode electrical arc generating system, in which an arc 902 is formed between an electrode 904 and a electrically charged metal wire feedstock 906. Configurations include a “parallel” configuration (FIG. 9A), a “perpendicular” configuration (FIG. 9B), a “slash” configuration (FIG. 9C), a “V” configuration (FIG. 9D), and an “inverted V” configuration (FIG. 9E).

Other sources of heat may be used to vaporize the metal feedstock in addition to an electrical arc. In one embodiment, an induction coupled plasma source may be used to produce the metal vapor.

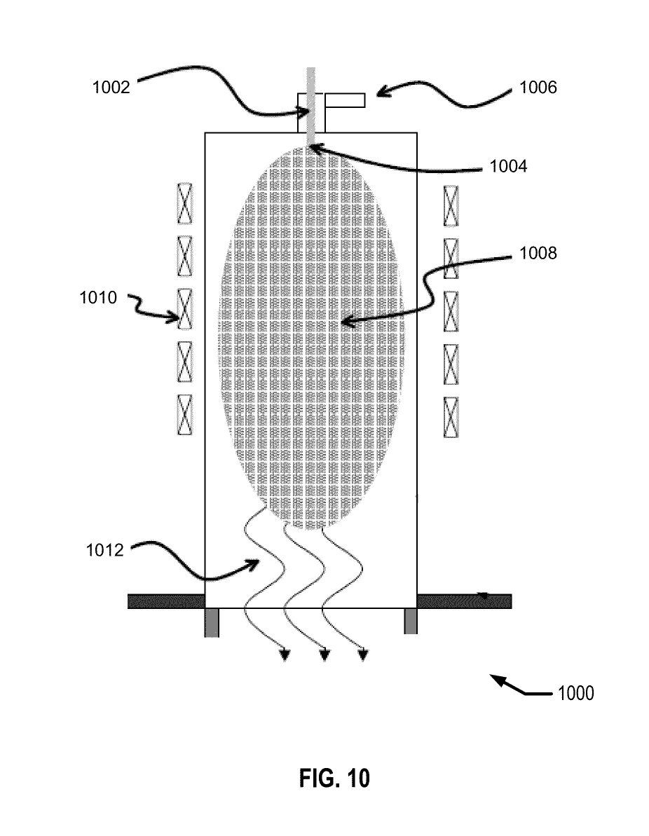

An exemplary embodiment of an induction coupled plasma metal vapor source is illustrated in FIG. 10. One or multiple metal wires 1002 are fed down into an induction coupled plasma (ICP) 1008. One or more reactive gases such as nitrogen, nitrogen-argon, nitrogen-hydrogen, ammonia or other suitable reactive gas mixes are pumped into the ICP reactor 1000 through a gas feed inlet 1006. The ICP 1008 is produced from the inductively coupling of the gas mix to an induction coil 1010. At the point 1004 where the wire 1002 and the ICP 1008 intersect, heat from the ICP 1008 vaporizes the wire 1002, resulting in a high temperature metal vapor and reactive gas mix 1012. The mixture 1012 is transported into the heater unit where the single crystal is produced. In other embodiments, a similar design may be used in which the coupled plasma source is replaced by a DC plasma source, a laser source, or a microwave source.

### 4. Gas Delivery System

The gas delivery system 408 delivers at least one reactive species to the reactor housing 502. The gas delivery system 408 includes a number of devices that deliver gas to the reactor housing 502. The at least one reactive species may form the vapor mixture with which the metal compound will be condensed to form the single crystal, and may also be used to purge the reactor of unwanted gases such as air or oxygen. The gases may also cool the inlet end of the reactor housing 502. The particular gas composition supplied to the reactor may be selected depending on the desired composition of the singe crystal to be produced. The gas mixture may include a reactive gas as well as a doping gas used to produce a doped single crystal composition. The doping gas may be selected to enhance the p-type or n-type conductivity of the bulk crystals produced by the process described herein.

Non-limiting examples of reactive gas species suitable for use in the gas delivery system 408 in the production of single crystals include nitrogen, oxygen, carbon dioxide, NH₃ CH₄, C₂H₂, C₃H₈, B₂H₆, AsH₃, H₂S, SiH₄, GeH₄, GeCl₄, dimethylberyllium, trimethlylgallium, trimethylindium, triethylgallium, triethylindium, di-isopropylmethylindium, ethyldimethylindium, Isobutylgermane, dimethylamino germanium trichloride, tetramethylgermane, tetraethylgermane, and combinations thereof.

The composition of the gas mixture introduced to the reactor may be uniform to grow a single crystal with a uniform composition. Alternatively, the composition of the gas mixture may be abruptly varied from one composition to another to grow a single crystal with discrete layers of different compositions. In one embodiment, the composition of the gas mixture can be abruptly changed, in real-time, during the growth process, thereby changing the composition of the crystal. In another embodiment, the composition of the gas mixture may be varied gradually over time to produce a gradient within the composition of the crystal.

The gas delivery system 408 may include a gas supply tube connected to a gas source. The gas source may include a pressurized gas container and a connection fitting hydraulically connected to one end of the gas supply tube. The exit port at the opposite end of the gas supply tube is inserted into the reactor and reactive gases are directed toward the vaporization inlet of the metal vapor system 406. In other embodiments the reactive gases may be directed further downstream of the vaporization inlet. The gas delivery system may further include a manual or electrically controllable pressure valve to control the rate of flow of reactant gases into the reactor. Depending on the particular crystal production process, the reactive gases may be delivered at a total pressure ranging from about 0.01 ATM to about 20 ATM and a temperature ranging from about room temperature to about 2500° C. The gas supply tube may be constructed of any suitable material known in the art, and may further include insulation to prevent heating of the reactive gas mixture as it enters the reactor housing 502.

FIG. 5 shows the insertion of a gas supply tube 532 through the inlet end cap 508 of the reactor housing 502. Reactive gases are introduced into the reactor housing 502 through the gas supply tube 532 just downstream of the electrical arc 540. In one embodiment, the metal wire 538 is fed through the center of the gas supply pipe 532.

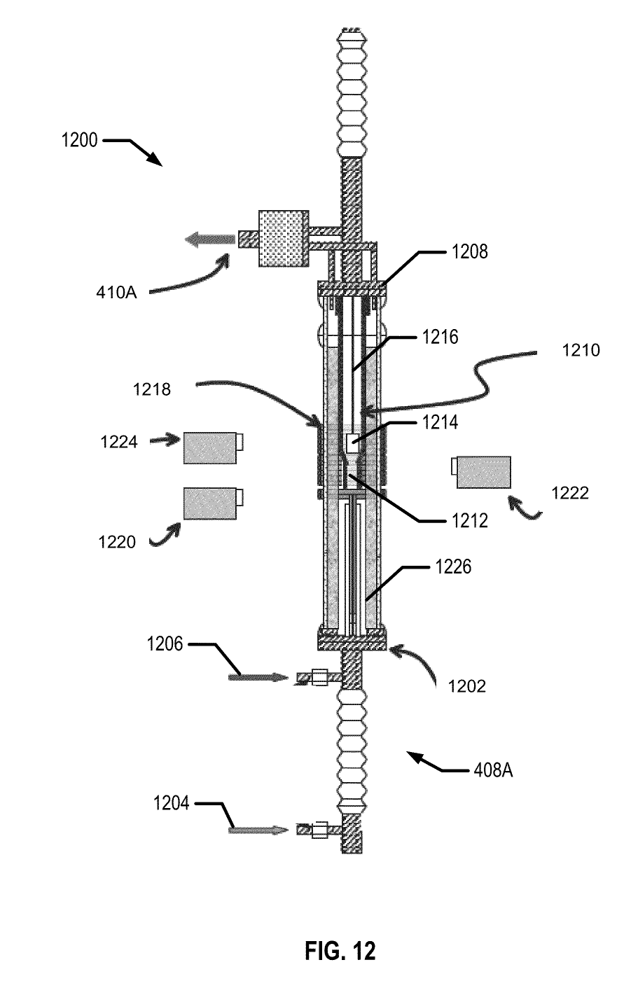

FIG. 12 is an illustration of another embodiment of a reactor 1200 showing the integration of the gas delivery system 408A with other reactor components. The inlet end cap 1202 is attached to the gas delivery system 408A that provides both purge gas 1204 and reactive gas 1206. The inlet end cap 1202 is also connected to the wire stepper motor system from the metal vapor system 406 (not shown). The outlet end cap 1208 is connected to both the rotational/translational/weighing system 404 (not shown) and the vacuum system 410A. Gases flows through the reactor 1200 from the gas delivery system 408A up through the main heating unit 1210 and out the outlet end cap 1208 into the vacuum system 410A.

### 5. Vacuum System

The vacuum system 410 may be attached to an exit end of the reactor housing 502 in various embodiments. The vacuum system removes oxygen and other unwanted atmospheric gases from the interior of the reactor housing 502 prior to starting a crystal formation process. Additionally, the vacuum system 410 may be used to generate a gas flow within the reactor housing 502 by exhausting the gases introduced at the inlet end of the reactor housing 502 out through the exit end of the reactor housing 502.

The vacuum system 410 may include a vacuum source that may include at least one vacuum pump and at least one vacuum tube attached to the vacuum pump at one end. The opposite end of each of the vacuum tubes is hydraulically connected to a vacuum attachment fitting at the exit end of the reactor housing 502.

FIG. 5 illustrates the attachment fittings of an exemplary reactor housing 502. The one or more vacuum tubes of the vacuum system 410 may connect to the reactor housing 502 via fittings on the outlet end cap 506. A vacuum fitting 550 on the end of the purge tube 536 nearest the exposed surface of the outlet end cap 506 may be used to hydraulically connect the vacuum system 410 to the reactor housing 502. In addition, the one or more vacuum tubes may hydraulically connect to an exhaust fitting 548 within the outlet end cap 506. The vacuum applied at the one or more purge tubes 536 may be used to control the interior pressure of the reactor housing 502 to a pressure ranging from about 0.01 ATM to about 20 ATM. The vacuum applied at the exhaust fitting 548 may be used to control the rate of flow of gases through the heater 510.

The vacuum system 410 may further include a vacuum valve to control the amount of vacuum pressure applied to the reactor. The vacuum valve may be set and adjusted manually by an operator of the reactor housing 502, or the vacuum valve may be electronically adjusted based on measured properties of the reactor housing 502 including temperatures, pressures, and the weight or size of the growing single crystal measured by the rotation/translation/weighing system 404.

The vacuum system 410 may include a two-stage pump. The first stage may be a mechanical vacuum pump used to reduce the base pressure within the reactor housing 502 to about 10⁻⁴ ton and to maintain the internal pressure during the crystal growth process by way of a butterfly valve. The second stage may be either a turbo pump or a diffusion pump used after completion of purging of the reactor to reduce the internal pressure of the reactor to about 10⁻⁹ torr.

### 6. Heater System

The elemental reaction between the metal vapor and the reactant gas, as well as the condensation of the metal compound vapor to form the single crystal of the metal compound takes place within the heater system 412 of the reactor housing 502. The heater system 412 provides a high temperature mixing chamber within which the metal compound vapor is formed. The heater system 412 also provides a growth chamber containing a temperature gradient within which the metal compound vapor condenses to form the single crystal. The heating system 412 includes a post-reaction chamber, held at temperature lower than the mixing chamber, to which the formed crystal may be moved to gradually cool down and through which unused reactants may be removed by the vacuum system 410.

Any method of generating heat may be used within the heater system 412. Non-limiting examples of suitable methods of heating for the heater system 412 include induction heating, resistive heating, and focused microwave heating. In a preferred embodiment, the heater system 412 is a radio frequency induction heater system. An exemplary heater system 412 is illustrated in FIG. 5.

An inductively heated main heater 510 may be held in place by a simple thread and nut system in which a threaded heater end 564 is secured to a mating heater connection fitting 534 formed within the inner surface of the outlet end cap 506. The opposite end of the heater may be sealed to the metal vapor system 406 near the electrical arc 540. The upward flow of gases through the heater from the electrical arc 540 to the outlet end cap 506 is enhanced by the thermal convection inside the main heater 510.

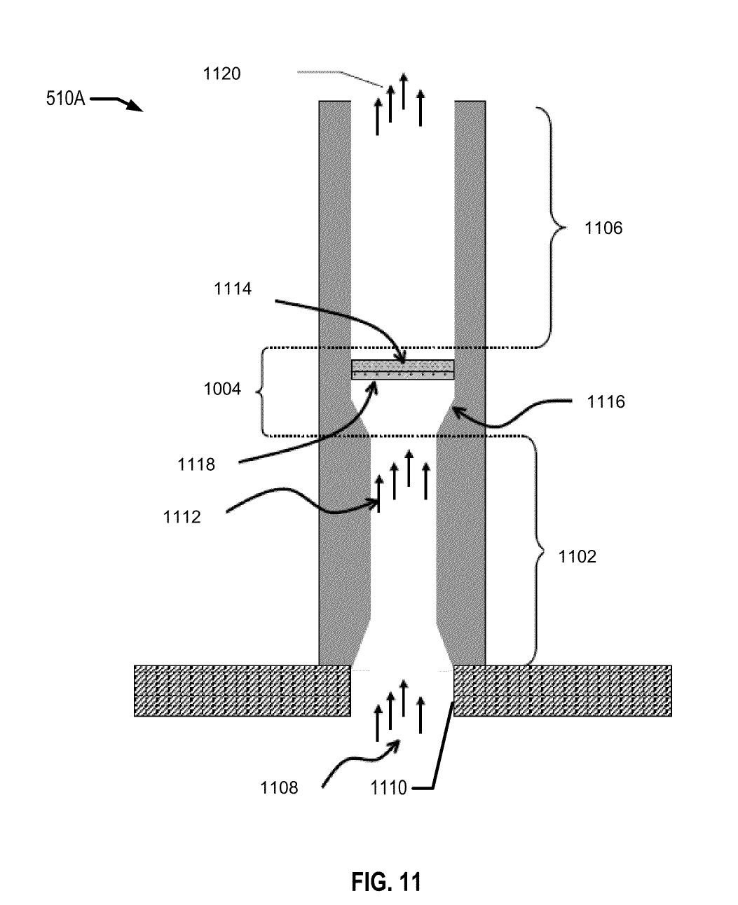

The temperature profile of the heater provides a spatial variation in temperature that may be used to perform the single crystal formation process. FIG. 11 is a schematic illustration of a heater 510. The open flow heater 510 includes three connected chambers: a mixing chamber 1102, a growth chamber 1104, and a post-reaction chamber 1106.

Reaction precursors including the metal vapor and the one or more reactive gases 1108 enter the heater 510 through the heater inlet 1110 into the mixing chamber 1102. The mixing chamber 1102 is maintained at a higher temperature than the other chambers 1104 and 1106 of the heater 510 in order to achieve a sufficiently high temperature to produce the metal compound vapor, such as an aluminum nitride vapor or a mixture of metal vapor and reactive gases, including but not limited to aluminum and nitrogen species. In one embodiment, the temperature of the mixing chamber 1102 is maintained at a temperature of at least 1700° C. In another embodiment, the temperature of the mixing chamber 1102 is maintained at a temperature of at least 2000° C.

The growth chamber 1104, is maintained at a lower temperature than the mixing chamber 1102, making possible the crystallization of the metal compound vapor 1112 onto the substrate 1114. The growth chamber 1104 may also include a throttle 1116 to decrease the gas velocity close to the substrate giving the reactive species and precursors more time to migrate on the surface of the substrate 1114 and the exposed surface of the growing single crystal 1118.

The post-reaction chamber 1106 has a temperature gradient that gradually decreases from the exit of the growth chamber 1104 to the exit 1120 of the reactor housing 500 This thermal gradient allows the previously grown single crystal material to cool down slowly and reduce any stresses produced during the crystal growth process. This section may also be held at a higher temperature to suppress build-up on the sidewalls of the post-reaction chamber 1106.

In one embodiment, the heater 510 includes a single stage heating system that has a single inductively heated region within the growth chamber 1104. Alternatively, the heater 510 may include a multiple stage heating system. For example, a three-stage heating system is illustrated in FIG. 12. The temperatures produced by the induction coil 1218 within each of the three chambers: mixing chamber 1212, growth chamber 1214, and post-reaction chamber 1216, are monitored by three separate infrared optothermometers 1220, 1222, and 1224, respectively. The chamber temperatures monitored by the optothermometers 1220, 1222, and 1224 may be used to continuously control the temperatures within the heater regions. The reactor 1200 may also include insulation 1226 to help maintain the desired temperature profile of the reactor 1200. Non-limiting examples of insulation 1226 include foam graphite, and refractory metal insulation. Other suitable insulations may be used. Foam graphite insulation 556 is also shown in another embodiment in FIG. 5.

The heater 510 may be a RF induction heating susceptor constructed from a single piece of a refractory material. Suitable refractory materials may have low chemical reactivity with any of the single crystal precursors including the metal vapor, the one reactant gases, or the metal compound vapor. Alternative, a particular material used to produce the heater may be selected in order to react with unused metal vapor to produce additional metal compound vapor. For example, in a reactor housing 502 producing aluminum nitride, zirconium nitride may be used to construct the heater 510 because aluminum vapor may react with zirconium nitride to produce aluminum nitride. In addition, suitable refractory materials may have good thermal conductivity and/or susceptibility to inductive heating. Non-limiting examples of refractory materials suitable for the construction of a heater 510 include tungsten, tungsten carbide, tantalum, tantalum carbide, zirconium, zirconium carbide, zirconium nitride, zirconium boride, Molybdenum, Niobium, and any alloys thereof.

### 7. Rotation/Translation/Weighing System

The rotation/translation/weighing (RTW) system 404 of the reactor system 400 measures continuously, the weight of the single crystal to assess the growth of the crystal. Additionally, the RTW system 404 repositions and rotates the growing crystal to enhance the quality, speed, and control of the crystal growth process. The RTW system 404 may include a substrate chuck on which a single crystal may be grown.

FIG. 5 is an illustration of an embodiment of the RTW system 404 within a reactor housing 502. The substrate 552 on which the single crystal is grown is attached to a substrate chuck 554. The substrate chuck 554 is attached to a support rod 558 at the end opposite to the substrate 552. The substrate chuck 554 is suspended within a growth chamber 560. The exposed face of the substrate 552 is oriented to face the metal compound vapor 542 formed in the mixing chamber 562 so that the metal compound vapor 542 or mixture of metal vapor and reactive gases may condense on the substrate 552, forming a single crystal. The support rod 558 may rotate about its own longitudinal axis in order to control the evenness of the condensation of the metal compound onto the substrate 552. In addition, the support rod 558 may translate upstream or downstream along the rod's longitudinal axis in order to position the exposed face of the substrate 552 within the thermal gradient maintained within the growth chamber 560, thereby providing control over the growth rate of the single crystal during growth.

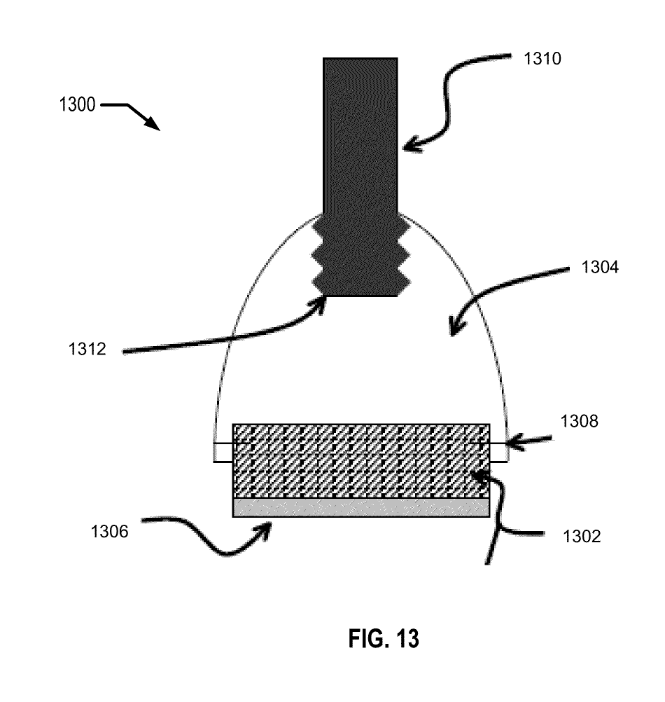

FIG. 13 is a more detailed illustration of an embodiment of a substrate chuck 1300. The substrate 1302 is attached to the RTW system 404 via the substrate chuck 1300. The substrate chuck 1300 includes a chuck housing 1304 and the substrate 1302. The substrate 1302 provides a surface on which the single crystal 1306 may be grown epitaxially. The substrate 1302 may be constructed from an ingot of polycrystalline metal compound of the same composition as the single crystal to be grown, a refractory metal, metal carbide, or a metal nitride.

The substrate chuck housing 1304 may be constructed from hot-pressed boron nitride covered by tantalum carbide, ZrN, W, or graphite coated with tantalum carbide. In a preferred embodiment, the substrate chuck housing 1304 is constructed from boron nitride. Boron nitride is preferred because this material is not susceptible to radio-frequency induction heating, resulting in a similar same heating profile throughout the growth process from the beginning of the growth process (when the temperature of the substrate chuck 1300 is important), to the end of the process, where the temperature of the bulk of the single crystal 1306 is more important.

The use of a polycrystalline ingot as the substrate material for crystal growth is also advantageous for further thermal control of the crystal growth process. Because the substrate and single crystal materials are matched in composition, a more native heat transfer occurs at the interface between the substrate 1302 and the substrate chuck housing 1304. As a result, the thermal stress placed on the substrate 1302 and the single crystal 1306 and related dislocations within the single crystal 1306 are reduced. The substrate 1302 may be attached to the substrate chuck housing 1304 using any suitable means known in the art. In one embodiment, a retaining pin 1308 may be used to attach the substrate 1302 to the substrate chuck housing 1304. The retaining pin 1308 may be produced using a material selected from tungsten, boron nitride, tantalum carbide, or any other suitable material known in the art. In another embodiment (not shown) the substrate 1302 may be attached to the substrate chuck housing 1304 using a fast-acting cyanoacrylate adhesive including but not limited to methyl 2-cyanoacrylate, ethyl-2-cyanoacrylate, n-butyl cyanoacrylate, or 2-octyl cyanoacrylate.

The end of the substrate chuck housing 1304 downstream of the substrate 1302 may be tapered or otherwise shaped to reduce the flow resistance of the substrate chuck 1300 as well as the maximum flow turbulence experienced by the substrate chuck 1300 in the post-reaction chamber of the heater (not shown).

The substrate chuck 1300 may be connected to the RTW system 404 via a thread and nut system 1312, in which the substrate chuck housing 1304 may be a threaded female fitting and a refractory metal support rod 1310 may end in a matching threaded male fitting. Non-limiting examples of suitable materials for the construction of the support rod 1310 include boron nitride, a refractory metal, a refractory metal nitride, and refractory metal carbide.

The end of the support rod 1310 opposite to the thread and nut system 1312 may be connected to a weight sensor and one or more actuators. The one or more actuators of the RTW system 404 may rotate the substrate chuck 1300, substrate 1302, and the attached single crystal 1306 during the crystal growth process, resulting in a more uniform crystallization across the growth surface 1314. Further, the one or more actuators may also translate the substrate chuck 1300, substrate 1302, and the attached single crystal 1306 during the crystal growth process within the growth chamber during the crystal growth process. A longitudinal thermal gradient is created in the downstream direction of the growth chamber. Therefore, the temperature at the growth surface 1314 of the crystal 1306 is greater than the temperature of the crystal near the substrate due to the increasing thickness of the growing crystal. The temperature gradient in the growth chamber influences the growth rate of the crystal 1306. For example, a larger temperature gradient allows a greater growth rate, but may also result in the increased formation of defects such as voids and dislocations. A smaller temperature gradient produces a higher quality crystal with a slower growth rate and fewer defects, however, the slower growth rate also results in decreased crystal size.

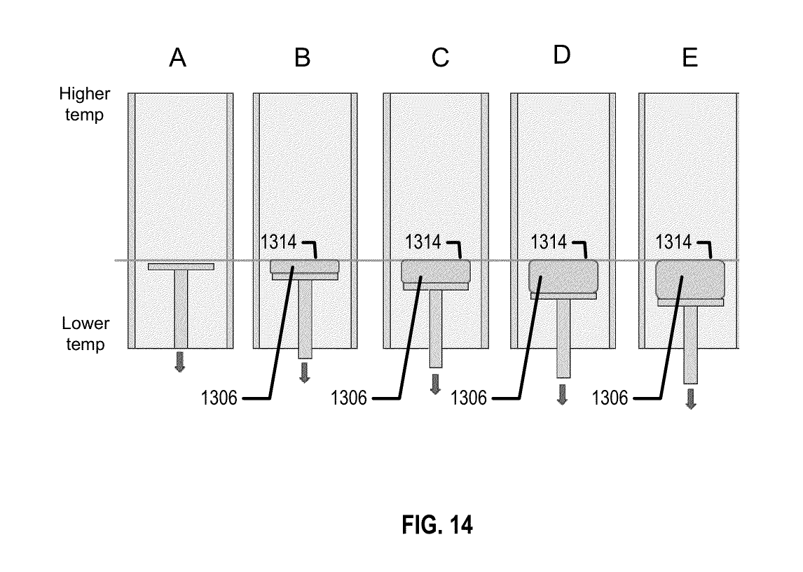

As shown in FIG. 14A-14E, the translation of the crystal 1306 within the growth chamber during crystal production allows the height of the crystal growth surface 1314 to be maintained at the same temperature, corresponding to a more optimal crystal growth rate. As the crystal 1306 grows up the growth chamber, the substrate chuck 1300 is pulled down, resulting in a growth surface that is maintained in essentially the same position and temperature, resulting in the crystal growing at an essentially constant rate. This positional adjustment results in controllable growth rates. Furthermore, the RTW system 404 allows for real time feedback and control of the growth rate during operation of the reactor. As the crystal grows in size, the weight of the crystal measured by the RTW system 404 increases proportionally, providing an estimate of the height of the crystal that may be used to reposition the substrate chuck 1300 within the growth chamber.

The position of the exposed crystal growth surface 1314 may be adjusted as the crystal grows in order to maintain an essentially constant growth rate during crystal production. Alternatively, the position of the exposed crystal growth surface 1314 within the growth chamber may be changed during crystal production, resulting in a crystal growth rate that varies during the production of the single crystal 1306. For example, the crystal may be grown at a very low rate initially, to insure that the single crystal contains relatively few defects to ensure strong bonding to the crystal growth substrate 1302, and to minimize internal stresses that may result in defects in the finished single crystal.

### 8. Feedback Control System

The processes executed within the reactor may be actively controlled by a feedback control system 414. The feedback control system 414 includes at least one sensor that monitors at least one process condition within the reactor. Non-limiting examples of a process condition includes a temperature, a pressure, and a flow rate measured at one or locations within the reactor, and a weight of the single crystal weight. Any suitable sensor may be used to monitor the process conditions, including but not limited to optothermometers, thermocouples, thermistors, piezoelectric pressure sensors, force transducers, and strain gages. The signal produced by the at least one sensor may be monitored by at least one processor included in the feedback control system 414. In addition, the processor may calculate and monitor a mathematical function of a process condition, including but not limited to the time rate of change of a process condition or the acceleration with respect to time of a process condition.

The at least one processor of the feedback control system 414 may generate at least one control command to alter a process condition based on any control scheme known in the art, including but not limited to any linear or non-linear control strategy. Any control command may be transmitted to one or more particular elements of the reactor in order to modify one or more operating conditions of the reactor. The modification to the operating conditions may result in a desired change in one or more process conditions, or in the maintenance of one or more process conditions at an essentially constant level. For example, the feedback control system 414 may generate a command to the heater system 412 to reduce the voltage of the applied electric field in response to an increase in the temperature within the mixing chamber to a temperature above a desired temperature range. Non-limiting examples of an operating condition that may be modified by commands from the feedback control system 414 include gas supply pressure, metal stock feed rate, vacuum pressure, and heater temperature.

### 9. Downflow Reactor Design

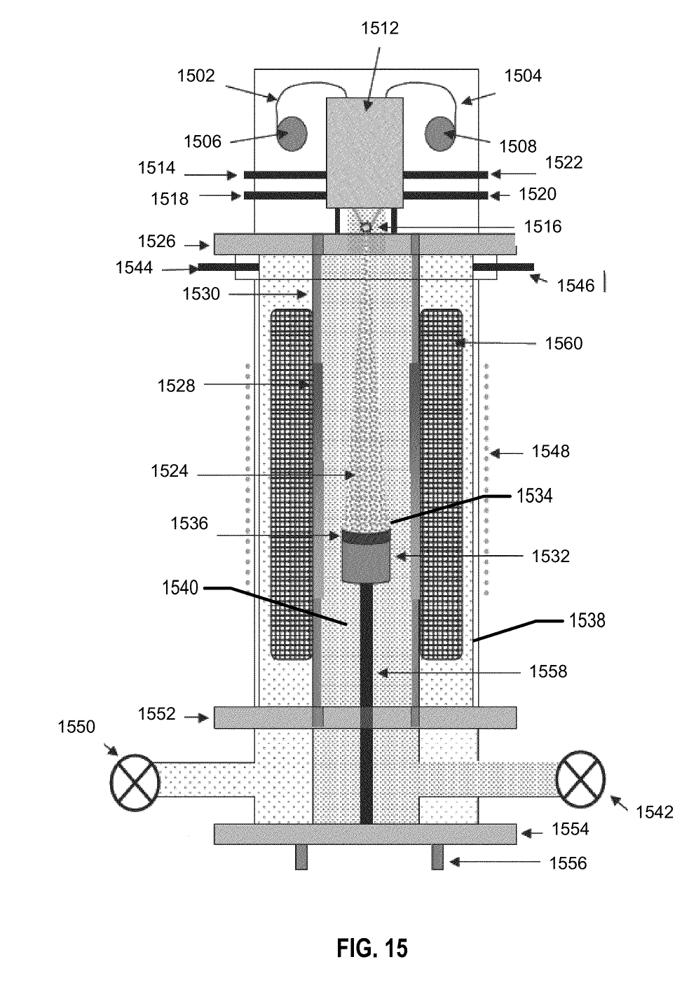

FIG. 15 illustrates an exemplary embodiment of a downflow reactor 1500 for the growth of single AN crystals. Two aluminum wires 1502 and 1504 are held on separate spools 1506 and 1508 inside the wire arc sub-system housing 1510. The wires 1502 and 1504 are drawn together by the wire arc head main unit 1512. The wire arc head main unit may be controlled externally by computer feedback control system commands 1514. Due to the large amount of electrical current placed on each wire, an electrical arc 1516 is produced at the point the two wires intersect that vaporizes a small length of the wires 1502 and 1504. The power for the electrical arc 1516 is supplied to the wire arc head main unit 1512 via an electrical power feed 1518.

Nitrogen and other dopant gases are flowed through the nitrogen gas inlet 1520 and dopant gas inlet 1522 into the middle of the electrical arc 1516. The resulting metal vapor and gas mixture 1524 is transported past the vacuum sealing top flange 1526 into the main heater 1528 through the mixing chamber 1530 and on to the substrate 1532 in the growth chamber 1534 where the resulting crystal 1536 is produced. The main heater 1528 may be separated from the main body of the reactor housing 1538, setting up inner and outer chambers inside the reactor housing.

Each chamber may be controlled by different vacuum systems. The flow is exhausted from the reactor out the post growth chamber 1540 to set up proper gas velocities and allow volumetric addition of additional Al vapor and nitrogen gas. This flow exhaust is achieved by the inner chamber vacuum control system 1542. The outer chamber is fed with nitrogen gas via the outer nitrogen gas feeds 1544 and 1546. The outer nitrogen gas feeds 1544 and 1546 cool the main heater 1528 ensuring that the heat from the induction coil 1548 does not travel up the main heater unit and destroy the integrity of the top flange's vacuum seal. The nitrogen gas also purges the outer chamber. The outer chamber uses a separate vacuum control system 1550 to purge and set the reaction pressure outside the main heater. The end of the reactor housing is sealed with the bottom flanges 1552 and 1554.

The bottom flange 1554 holds the substrate support system 1556 that in turn holds the substrate chuck 1558. The substrate chuck 1558 may be raised or lowered as needed during crystal production. The system temperature may be maintained with the inclusion of either graphite foam, refractory metal or other suitable insulation 1560 on the outside of the main heater unit.

### 10. Methods of Producing a Single Crystal of a Metal Compound

The devices and system can be used to provide and carry out a method of producing a single crystal of a metal compound by an elemental reaction of a metal vapor and a reactant gas. The method allows the growth of single crystal of a metal compound such as AlN using the reaction of pure or alloyed Al with N₂ gas or any other nitrogen bearing gas, while avoiding the parasitic formation of a polycrystalline nitrozation layer on the metal source that limits previous crystal growth methods.

The metal reactant is vaporized or melted by a heat source, such as an electrical arc. Because only a small cross-sectional area of the metal is heated and vaporized/melted at any given time, the surface area exposed to nitrozation or other surface chemistry effects is minimized. By reducing nitrozation of the metal, the rate of vaporization will not be greatly reduced. Furthermore, the bulk of the metal feedstock is held far away from the vaporization/melting site and is not held at high temperatures, allowing the storage of a large amount of metal feedstock in the reactor for an essentially continuous supply of metal feedstock.

The metal vapor is transported via gas flow, thermal convection, and or gravity into a heated mixing area that is maintained at a temperature above about 1700° C. and preferably above about 2000° C. The metal vapor reacts with the reactive gases, forming a metal compound sub-species. The metal compound sub-species then moves via gas flow, thermal convection, and/or gravity to a growth zone that is held at a lower temperature then the heated mixing area so that the metal compound vapor may crystallize.

The lower temperature in the growth zone allows the metal vapor compound to crystallize and form a single bulk crystal. The bulk crystal formation and subsequent growth may be initiated through seeded or non-seeded crystallization in the growth zone.

In a preferred embodiment a crystal seed or substrate, preferably composed of the same metal compound subspecies as the metal compound vapor, is placed in the growth zone. In this embodiment, the metal compound vapor precipitates onto the substrate to grow the single crystal.

In another embodiment, the single crystal may be formed through spontaneous self-nucleation of the metal compound sub-species once a sufficient density of the metal compound vapor has been accumulated in the growth zone. For example, the metal vapor compound is accumulated in the growth zone until a supersaturated vapor is formed. In this embodiment, the metal vapor compound may condense and form a single crystal on surfaces, such as the substrate chuck, within the growth zone.

The crystal formation process is velocity and volumetrically controlled by adjusting the exhaust pressure produced by the vacuum system hydraulically attached to the exit end of the reactor. Vaporized/melted metal may be continuously added into the heated mixing and growth chambers. The exhaust pressure regulates and sets the driving force for the movement of the metal vapor, reactive gas, and metal compound vapor mixture, which in turn governs the gas flow rates in addition to as well as thermal convection and or gravity for the transport of reactants through the open flow reactor.

While the disclosure has been explained in relation to exemplary embodiments, it is to be understood that various modifications thereof will become apparent to those skilled in the art upon reading the description. Therefore, it is to be understood that the disclosure disclosed herein is intended to cover such modifications as fall within the scope of the appended claims.

What is claimed is:

1. An open-flow reactor system for continuous growth of a single crystal of a metal compound by an elemental reaction of a metal vapor and a reactant gas, the reactor system comprising:
a metal vapor system to provide the metal vapor by continuously vaporizing a metal feedstock; and;
a rotation-translation-weighing system to monitor the weight of the single crystal as it grows and to reposition the crystal to a position suitable for continued growth within the reactor.

2. The reactor of claim 1, wherein the metal feedstock is a metal supply selected from a metal powder, a metal wire, a metal tube, a metal rod, a liquid metal, a metal bar, and combinations thereof

3. The reactor of claim 1, wherein the metal vapor source comprises a metal heating source.

4. The reactor of claim 3, wherein the metal heating source is selected from an electrical arc source, a D.C. plasma source, an inductively coupled plasma source, a laser source, and a microwave source.

5. The reactor of claim 4, wherein the electrical arc source comprises an anode and a cathode electrically attached to a voltage source, the anode, and cathode are separated by a gap, and the metal feedstock is fed into an electrical arc formed between the cathode and the anode to form the metal vapor.

6. The reactor of claim 5, wherein the electrical arc is continuous.

7. The reactor of claim 5, wherein the electrical arc is generated as a series of discrete arcs, and the metal feedstock is fed into the electrical arc in a discrete series of small amounts timed to coincide with the series of discrete arcs between the anode and cathode.

8. The reactor of claim 4, wherein the electrical arc source comprises a first metal feedstock and an electrode, the first metal feedstock and the electrode electrically attached to a voltage source.

9. The reactor of claim 4, wherein the electrical arc source comprises the metal feedstock and a second metal feedstock, the first metal feedstock and the second metal feedstock electrically attached to a voltage source.

10. The reactor of claim 1, wherein the rotation-translation-weighing system comprises a crystal growth substrate operatively attached to a force transducer.

11. The reactor of claim 10, wherein the crystal growth substrate is further operatively attached to at least one actuator to move the crystal growth substrate in at least one movement selected from rotation about a longitudinal axis and translation along a longitudinal axis.

12. The reactor of claim 11, wherein the at least one movement is selected to reposition the crystal to the position suitable for continued growth within the reactor.

13. The reactor of claim 1, wherein the reactor further comprises a heater system to heat the metal vapor and the reactant gas to a reaction temperature to form a metal compound vapor.

14. The reactor of claim 13, wherein the heater system comprises a material that is heat-resistant up to a temperature of about 120% of the reaction temperature formed into a thin-walled tubular structure.

15. The reactor of claim 14, wherein the heater system is an induction heater.

16. The reactor of claim 1, wherein the reactor further comprises a gas source.

17. The reactor of claim 1, wherein the reactor further comprises a vacuum system.

18. The reactor of claim 1, further comprising a feedback control system comprising:
at least one sensor to monitor at least one process condition comprising single crystal weight, temperature, pressure, and flow rate measured in at least one location within the reactor; and,
at least one processor to generate at least one control command to alter a process condition comprising gas supply pressure, metal stock feed rate, vacuum pressure, and heater temperature comprising a mathematical function of at least one feedback signal comprising any of the at least one process conditions, the time rate of change of any one of the process conditions, the acceleration with respect to time of any of the process conditions, and combinations thereof.

19. An open-flow reactor for the growth of a single crystal of a metal compound by an elemental reaction of a metal vapor and a reactant gas, comprising:
a metal feedstock comprising one or more metals selected from a metal and a doping metal;
a metal heating source for vaporizing the metal feedstock;
a reactant gas source;
a crystal growth substrate;
an actuator for positioning the crystal growth substrate within the open-flow reactor; and,
a force transducer mechanically connected to the crystal growth substrate to monitor the weight of the single crystal as it grows.

20. The reactor of claim 19, wherein the actuator rotates the crystal deposition substrate.

21. The reactor of claim 19, wherein the metal feedstock is selected from a metal powder, a metal wire, a metal tube, a metal rod, a liquid metal, a metal bar, and combinations thereof

22. The reactor of claim 19, wherein the metal heating source is selected from an electrical arc source, a D.C. plasma source, and an inductively coupled plasma source.

23. The reactor of claim 22, wherein the electrical arc source comprises an anode and a cathode electrically attached to a voltage source, the anode and cathode are separated by a gap, and the metal feedstock is fed into an electrical arc formed between the cathode and the anode to vaporize the metal feedstock.

24. The reactor of claim 23, wherein the electrical arc is generated continuously, and the metal feedstock is fed into the electrical arc in a discrete series of small amounts.

25. The reactor of claim 23, wherein the electrical arc is generated as a series of discrete arcs, and the metal feedstock is fed into the electrical arc in a discrete series of small amounts timed to coincide with the series of discrete electrical arcs between the anode and cathode.

26. The reactor of claim 23, wherein the electrical arc source comprises the metal feedstock and an electrode electrically attached to a voltage source, the metal feedstock and electrode are separated by a gap, the metal feedstock is vaporized by an electrical arc formed in the gap to form the metal vapor, and the metal feedstock is fed into the gap to replace the vaporized metal feedstock.

27. The reactor of claim 23, wherein the electrical arc source comprises the metal feedstock and a second metal feedstock electrically attached to a voltage source, the metal feedstock and the second metal feedstock are separated by a gap, the metal feedstock and the second metal feedstock are vaporized by an electrical arc formed in the gap to form the metal vapor, and the metal feedstock and the second metal feedstock are fed into the gap to replace the vaporized metal feedstocks.

28. The reactor of claim 19, wherein the reactor further comprises a heater to heat the metal vapor and the reactant gas to a reaction temperature to form a metal compound vapor, and to provide a decreasing temperature gradient within which the metal compound vapor may condense to form the single crystal.

29. The reactor of claim 28, wherein the heater comprises a material that is heat-resistant up to a temperature of about 120% of the reaction temperature, wherein the material is formed into a thin-walled tubular structure.

30. The reactor of claim 28, wherein the heater is an induction heater and the material is a susceptor material.

31. The reactor of claim 19, wherein the reactor further comprises a gas source to provide at least one reactant gas to the reactor at the metal heating source.

32. The reactor of claim 19, wherein the reactor further comprises a vacuum source to:
create a vacuum within a volume outside of the heater;
draw a reactant flow comprising the metal vapor and the reactant gas into the heater; and,
draw a crystallization flow comprising the metal compound vapor past the crystal growth substrate.

33. The reactor of claim 19, further comprising a feedback control system comprising:
at least one sensor to monitor at least one process condition comprising single crystal weight, temperature, pressure, and flow rate measured in at least one location within the reactor; and
at least one processor to generate at least one control command to alter a process condition comprising gas supply pressure, metal stock feed rate, vacuum pressure, and heater temperature comprising a mathematical function of at least one feedback signal comprising any of the at least one process conditions, the time rate of change of any one of the process conditions, the acceleration with respect to time of any of the process conditions, and combinations thereof.

34. An open-flow reactor system for the growth of metal compound crystals, the reactor system comprising:
a metal heating source comprising a vaporization region situated between a vaporization inlet and a vaporization outlet;
a metal feedstock comprising a metal storage container and a protruding free end, wherein the protruding free end is inserted through the vaporization inlet into the vaporization region;
a gas supply tube comprising an exit port at one end and a gas supply connection at an opposite end of the gas supply tube, wherein the exit port is situated near the vaporization inlet and aimed at the vaporization region;
a gas source comprising a pressurized gas container and a connection fitting, wherein the connection fitting is hydraulically connected to the gas supply connection of the gas supply tube;
a hollow thin-walled heater defining a continuous internal volume opening to a heater inlet formed at one end of the heater and to a heater exit formed at an opposite end of the heater, wherein:
the heater inlet is hydraulically sealed to the vaporization outlet of the metal heating source; and,
the continuous internal volume comprises a mixing chamber, a crystal growth chamber comprising a growth inlet and a growth outlet, and a post-reaction chamber, wherein:
the mixing chamber opens to the heater inlet and to the growth inlet at opposite ends;
the crystal growth chamber opens to the growth inlet and the growth exit at opposite ends; and,
the post-reaction chamber opens to the growth exit and to the heater exit at opposite ends;
a thin sheet crystal growth substrate comprising a recrystallization face and an opposing mounting face situated within the crystal growth chamber, wherein the recrystallization face is exposed to the growth inlet;
a substrate chuck comprising a attachment face and an opposing rod attachment face, wherein the attachment face is adhered to the mounting face of the crystal growth substrate;
an elongate support rod comprising an attachment fitting at one end and an actuator fitting at an opposite end of the support rod, wherein the attachment fitting is attached to the attachment face of the substrate chuck;
a weight sensor and at least one actuator attached to the actuator fitting of the elongate support rod;
a reactor housing comprising a thin-walled hollow reactor body, a inlet end cap and an outlet end cap, wherein:
the reactor body defines a reactor volume sealed at one end by an interior surface of the inlet end cap and by an interior surface of the outlet end cap at an opposite end of the reactor body;
the vaporization inlet of the metal heating source is sealed to the interior surface of the inlet end cap and opens to the exterior of the reactor housing through a reactor inlet channel running through the inlet end cap; and,
the heater exit is sealed to the interior surface of the outlet end cap and opens to the exterior of the reactor housing through a reactor outlet channel running through the outlet end cap;
at least one purge tube running through the outlet end cap from the exterior of the reactor housing to the reactor volume external to the continuous internal volume of the heater, wherein each purge tube comprises a vacuum attachment fitting at an end of the purge tube external to the reaction housing, and a purge tube inlet at the end of the purge tube in contact with the reactor volume; and,
a vacuum source comprising a vacuum pump and at least one vacuum tube, wherein one end of each vacuum tube is hydraulically connected to the vacuum pump and an opposite end of each vacuum is hydraulically connected to the vacuum attachment fitting of one or more of the one or more purge tubes, the heater exit, or any combination thereof.

35. The reactor of claim 34, wherein the metal heating source further comprises an anode and a cathode electrically connected to a power source, wherein the anode and cathode generate an electrical arc within the vaporization region formed in a gap between the anode and the cathode.

36. The reactor of claim 35, wherein either the cathode or anode are replaced by the free end of the metal feedstock, wherein the free end is further electrically connected to the power source.

37. The reactor of claim 35, wherein the cathode and the anode are replaced by the free end of the metal feedstock and a second free end of a second metal feedstock, wherein the free end and the second free end are further electrically connected to the power source.

38. The reactor of claim 34, wherein the metal storage container further comprises an amount of replenishable metal supply and a metal feed actuator operatively connected to the metal stock.

39. The reactor of claim 38, wherein the replenishable metal supply is selected from a metal powder, a metal wire, a metal tube, a metal rod, and a metal bar.

40. The reactor of claim 34, wherein the gas supply tube further comprises an insulating layer situated around the external surface of the gas supply tube.

41. The reactor of claim 34, wherein the growth exit of the crystal growth chamber has a larger cross-sectional area than the growth inlet, forming a throat.

42. The reactor of claim 41, wherein the crystal growth substrate is situated within the throat.

43. The reactor of claim 34, wherein the reactor further comprises a feedback control system comprising:
a feedback processor comprising at least one sensor input and at least one control command output; and,
at least one sensor selected from a force transducer, a pressure sensor, a temperature sensor, and a flow sensor, wherein:
each of the at least one sensors is operatively connected to one of the at least one sensor inputs of the processor;
each of the at least one sensors monitors a reactor condition comprising temperature and flow rate at locations within the reactor comprising the reactor volume external to the heater, the exit port of the gas supply tube, the vaporization region of the metal heating source, the mixing chamber of the heater, the crystal growth chamber, the post-reaction chamber, the inlet of the purge tube, the vacuum source, the volume external to the reactor housing, and the weight of the single crystal; and,
each of the at least one control command outputs is operatively connected to a control of the reactor comprising a vacuum pressure setting, a heater temperature setting, a gas supply pressure setting, a metal feedstock actuator setting, a vaporization temperature setting, and a crystal growth substrate actuator setting.
